(19) United States
(12) Patent Application Publication
(10) Pub. No.: US 2026/0255929 A1
(43) Pub. Date: Aug. 27, 2026

(54) PEDESTAL ASSEMBLY

(71) Applicant: Lam Research Corporation, Fremont, CA (US)

(72) Inventors: Miguel Benjamin Vasquez, Portland, OR (US); David French, Fort Myers, FL (US); Patrick G. Breiling, Tigard, OR (US); Jacob Lee Hiester, Newberg, OR (US)

(73) Assignee: Lam Research Corporation, Fremont, CA (US)

(21) Appl. No.: 19/163,342

(22) PCT Filed: Mar. 8, 2024
(86) PCT No.: PCT/US2024/019240

§ 371 Date: Sep. 8, 2025

Related U.S. Application Data
(60) Provisional application No. 63/495,048, filed on Apr. 7, 2023.

(51) Int. Cl. H10P 72/76; H01J 37/32

(52) U.S. Cl. CPC H10P 72/7626; H01J 37/32183; H01J 37/32513; H01J 37/32577; H01J 37/32724

(57) ABSTRACT

A pedestal assembly is disclosed. In at least one implementation, pedestal assembly comprises a pedestal that comprises a platen and a stem attached to the platen. An adapter tube is attached to the stem. In at least one implementation, cooling collar is coupled to the adapter tube. A transition conduit is coupled to the cooling collar. In at least one implementation, an electrical enclosure is coupled to the transition conduit. In at least one implementation, electrical enclosure comprises a radio frequency (RF) connector block and a heater connector block. In at least one implementation, the RF connector block is coupled to the platen. In at least one implementation, the heater connector block is coupled to the platen.

### CLAIM FOR PRIORITY

This application claims priority to U.S. Provisional Patent Application No. 63/495,048, filed on Apr. 7, 2023, titled “Pedestal Assembly,” which is incorporated by reference in its entirety for all purposes.

### BACKGROUND

Process tools in the semiconductor industry provide essential fabrication capabilities for semiconductor device manufacture. Many processes involving layer deposition require heating semiconductor substrates (e.g., wafers) to high temperatures (over 600° C.) for driving some surface reactions for layer formation and etching processes. High temperatures produced at the wafer chuck can be somewhat problematic as heat can be readily transferred by conduction and radiation from the wafer chuck to the wafer pedestal below the wafer chuck. Temperature sensitive parts and components on and within the pedestal can be adversely affected unless modifications have been undertaken to reduce impact of employment of high wafer chuck temperatures.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale and exact locations. For example, the dimensions of some elements can be exaggerated relative to other elements for clarity. Also, various physical features can be represented in their simplified “ideal” forms and geometries for clarity of discussion, but it is nevertheless to be understood that practical implementations can only approximate the illustrated ideals. For example, smooth surfaces and square intersections can be drawn in disregard of finite roughness, corner-rounding, and imperfect angular intersections characteristic of structures formed by nanofabrication techniques. Further, where considered appropriate, reference labels have been repeated among the figures to indicate corresponding or analogous elements.

FIG. 1A illustrates a profile view of a pedestal assembly in accordance with at least one implementation.

FIG. 1B illustrates a cross-sectional view of the pedestal assembly shown in FIG. 1A, showing internal components, in accordance with at least one implementation.

FIG. 2A illustrates a plan view of a cooling collar in accordance with at least one implementation.

FIG. 2B illustrates a 3D perspective view of one of the half portions of the cooling collar shown in FIG. 2A, in accordance with at least one implementation.

FIG. 3A illustrates a plan view of a cooling collar, in accordance with at least one implementation.

FIG. 3B illustrates a 3D perspective view of the cooling collar shown in FIG. 3A, in accordance with at least one implementation.

FIG. 4 illustrates a 3D perspective view of a transition conduit in accordance with at least one implementation.

FIG. 5 illustrates a 3D perspective view of an orientation ring in accordance with at least one implementation.

FIG. 6A illustrates a plan view of an attachment flange viewed from an upper surface, in accordance with at least one implementation.

FIG. 6B illustrates a plan view of the attachment flange shown in FIG. 6A, viewed from a lower surface, in accordance with at least one implementation.

FIG. 6C illustrates a 3D perspective view of the attachment flange shown in FIG. 6B viewed from an upper surface, in accordance with at least one implementation.

FIG. 7A illustrates a plan view of an electrical enclosure viewed from an upper panel, in accordance with at least one implementation.

FIG. 7B illustrates a plan view of the electrical enclosure shown in FIG. 7A, viewed from a lower panel, in accordance with at least one implementation.

FIG. 7C illustrates a plan view of the electrical enclosure shown in FIG. 7A, viewed from lower side, with the lower panel removed to show the interior of the electrical enclosure and circuitry, in accordance with at least one implementation.

FIG. 8A illustrates a 3D perspective view of a filter board subassembly viewed from the rear side, in accordance with at least one implementation.

FIG. 8B illustrates a 3D perspective view of the filter board subassembly shown in FIG. 8A viewed from the front side, in accordance with at least one implementation.

FIG. 9 illustrates a block diagram of electronic circuitry contained within the electrical enclosure, in accordance with at least one implementation.

FIG. 10A illustrates a 3D perspective view of a partially assembled RF connector, in accordance with at least one implementation.

FIG. 10B illustrates a 3D perspective view of a fully assembled view of the RF connector shown in FIG. 10A, in accordance with at least one implementation.

FIG. 10C illustrates a 3D perspective view of an implementation of the RF connector shown in FIG. 10B, in accordance with at least one implementation.

### DETAILED DESCRIPTION

In at least one implementation, a pedestal assembly having enhanced cooling performance and subassembly designs that simplify installation is described. In at least one implementation, pedestal assembly can be part of a process tool for fabrication of semiconductor devices. In at least one implementation, process tool can comprise a vacuum process chamber. In at least one implementation, pedestal assembly can be contained at least partially within vacuum chamber, and extend through a wall of vacuum chamber into surrounding atmosphere. In at least one implementation, pedestal assembly comprises a platen and a stem descending from platen. In at least one implementation, stem can be a tubular structure, comprising a tubular wall surrounding a hollow interior. In at least one implementation, platen comprises an electrostatic chuck for electrostatically securing a semiconductive substrate to platen.

In at least one implementation, platen and stem comprise a high thermal conductivity (k) ceramic material such as, but not limited to, aluminum nitride (k~300 W/mK). During operation, wafer pedestal can be heated to temperatures of 650° C. or greater. Heat can be transferred to other parts of pedestal assembly by longitudinal (e.g., lengthwise) conduction through wall of stem and by radiation to radio frequency (RF) and low-frequency (e.g., 60 Hz) alternating or direct current (DC) conductors routed through stem. In at least one implementation, pedestal assembly further comprises an adapter tube coupled to base of stem and providing a transition from wafer pedestal to a cooling collar coupled to base of adapter tube. In at least one implementation, adapter tube can also comprise a metal such as stainless steel or aluminum. In at least one implementation, adapter tube comprises a ceramic material such as aluminum nitride. In at least one implementation, an o-ring can be employed to for a gas seal at a joint between a neck of cooling collar and adapter tube. In at least one implementation, o-ring can be seated within a groove on neck. In at least one implementation, o-ring can comprise an elastomer that can begin to melt at temperatures above 150° C.

In at least one implementation, cooling collar comprises a circular flange at base of neck. In at least one implementation, an internal conduit extends within flange for flowing a cooling fluid, such as water, through flange. During operation, cooling fluid can enhance heat removal from pedestal assembly by convective heat transfer from solid portions of cooling collar to moving fluid. In at least one implementation, cooling fluid flowing within flange can absorb sufficient heat to cool neck below a critical or maximum temperature that can be within thermal tolerances of o-ring. In at least one implementation, cooling collar comprises materials having high thermal conductivity (e.g., greater than 200 W/mK), such as copper and/or aluminum. During operation, high thermal conductivity of solid material of cooling collar can ensure rapid heat transfer from adapter tube and neck of cooling collar to cooling fluid.

In at least one implementation, pedestal assembly further comprises an electrical subassembly. In at least one implementation, electrical subassembly comprises an electrical enclosure and a tubular transition conduit attached (e.g., by fasteners) to an upper panel of electrical enclosure. In addition to providing a connection and distribution nexus for external RF and DC power sources and pedestal assembly, electrical enclosure can house circuitry operable to perform RF filtering and impedance matching functions. In at least one implementation, circuitry can provide low pass filtering or RF choking functions. These filtering functions can be operable to attenuate any RF voltages and currents that can appear on DC heater conductors by electromagnetic coupling to nearby RF conductors. In at least one implementation, electrical housing subassembly can be mechanically coupled to pedestal assembly by transition conduit. In at least one implementation, transition conduit extends between electrical enclosure and cooling collar. In at least one implementation, transition conduit can be fastened to upper panel of electrical enclosure by a flange.

In at least one implementation, transition conduit can be fastened to flange of cooling collar. In at least one implementation, electrical conductors extending from electrical subassembly to pedestal pass through transition conduit into adapter tube and stem. In at least one implementation, electrical conductors carrying RF and/or DC power can be routed to RF electrodes and electrostatic clamping electrodes embedded within pedestal. In at least one implementation, conductors carrying DC or low-frequency AC power to resistive heaters or heating elements embedded within pedestal are also routed through adapter tube and stem, originating from electrical housing subassembly.

In at least one implementation, electrical conductors comprise rigid RF conductor rods and DC heater conductor rods that extend through column of pedestal assembly (e.g., column comprising transition conduit, cooling collar, adapter tube and stem). In at least one implementation, an electrical subassembly comprises electrical connector blocks extending through upper panel of electrical enclosure. In at least one implementation, connector blocks provide an interface between RF conductor rods and DC heater conductor rods and circuitry within electrical enclosure. In at least one implementation, connector blocks are coupled to circuit boards housed within electrical enclosure. In at least one implementation, connector blocks extend into transition conduit through openings in upper panel of electrical enclosure and flange coupling transition conduit to electrical enclosure. In at least one implementation, connector blocks can comprise banks of plug-in or bayonet style terminals, enabling RF conductor rods and heater conductor rods to dock securely to electrical enclosure for both mechanical and electrical coupling. In at least one implementation, a first connector block, dedicated to transferring heater power out of electrical enclosure to pedestal, can comprise four terminals to seat four heater conductor rods. In at least one implementation, a second connector block, dedicated to transferring RF power from electrical enclosure to pedestal, can comprise three terminals to seat three RF conductor rods.

In at least one implementation, pedestal assembly can be physically suspended from an external surface of bottom wall of vacuum chamber by a frame (e.g., an articulating framework). In at least one implementation, frame comprises multiple extensible members that are independently controllable to extend and contract. In at least one implementation, frame can comprise three to six extensible members. In at least one implementation, extensible members can each comprise a linear drive actuator. In at least one implementation, extensible members are attached to upper mounts affixed on external surface of bottom wall of vacuum chamber and to lower mounts on upper panel of electrical enclosure. In at least one implementation, extensible members of frame can be operable to contract and extend in unison to raise and lower entire pedestal assembly. In at least one implementation, in addition to vertical motion, a frame can move pedestal assembly laterally by individualized control of extensible members. In at least one implementation, a frame can also tilt pedestal assembly by individual extensions and contractions of extensible members.

In at least one implementation, adapter tube of pedestal assembly extends through an opening in floor of a vacuum chamber. In at least one implementation, pedestal (including electrostatic chuck) and stem can be within vacuum chamber, whereas cooling collar, transition conduit and electrical subassembly can be outside (e.g., below) vacuum chamber. In at least one implementation, an opening in floor of vacuum chamber can be wider than diameter of adapter tube to allow for free motion of pedestal assembly, including lateral displacement and tilt of pedestal assembly by frame. In at least one implementation, a vacuum bellows through which adapter tube can pass can be fastened to bottom wall of vacuum chamber and fastened to cooling collar. In at least one implementation, a gasket or seal can be seated between rim of adapter tube base and a base flange of vacuum bellows to provide a vacuum seal against atmosphere. In at least one implementation, an opening in base flange of vacuum bellows allows neck of cooling collar to couple into adapter tube.

In at least one implementation, a mounting ring can be included around base flange of vacuum bellows. In at least one implementation, mounting ring can be fastened to base flange by bolts extending from cooling collar. In at least one implementation, lateral extensions from mounting ring can enable fasteners to be employed to rigidly secure lower portion of pedestal assembly, including cooling collar, transition conduit and electrical subassembly, together.

In at least one implementation, pedestal assembly comprises a gas inlet port for introduction of an inert gas into interior portions of pedestal assembly, displacing air that can infiltrate through vents in electrical enclosure. In at least one implementation, gas inlet port extends through a wall of transition conduit. In at least one implementation, a gas delivery tube can be coupled to gas inlet port within interior of transition conduit and extends to upper portion of pedestal assembly through adapter tube and stem. In at least one implementation, gas delivery tube can transport an inert gas, such as nitrogen or argon, to stem and inner surface of platen.

Atmospheric air can infiltrate into pedestal assembly through electrical enclosure. At high temperatures incurred in interior of upper portion of pedestal assembly (e.g., interior of stem), ceramic composition of stem and exposed surface of platen can react with gaseous oxygen and water vapor contained in air, shortening useful life of pedestal. During operation, inert gas introduced through gas inlet port can fill interior of stem and create a positive pressure in upper portion of pedestal assembly, displacing any oxygen and moisture from stem.

During operation, replacement of air in heated upper portion of pedestal assembly by an inert gas can mitigate oxygen infiltration into ceramic composition (e.g., aluminum nitride) of stem and platen, extending life of pedestal. For example, at high temperatures (above 500° C.), gaseous oxygen can migrate into bulk of aluminum nitride and displace nitride ions in bulk of grains or accumulate at grain boundaries, to form domains of aluminum oxide or oxygen-rich regions. Integrity of aluminum nitride can become compromised, and macroscopic cracks can eventually develop in stem and at junction of stem and platen, requiring replacement of pedestal.

In at least one implementation, pedestal assembly comprises a thermocouple port extending through wall of transition conduit. In at least one implementation, long leads from a thermocouple coupled to platen are routed through a shield tube that can be electrically coupled to thermocouple port. In at least one implementation, shield tube and thermocouple port can be electrically grounded to electrical enclosure through transition conduit and bottom cover. In at least one implementation, an electrically grounded shield tube can prevent RF pickup by long thermocouple leads (and thermocouple) due to electromagnetic coupling to RF from nearby RF conductors. In at least one implementation, accurate temperature readings from a thermocouple immersed in a strong RF environment can thus be enabled without necessitating electronic filtering.

Here, numerous specific details are set forth, such as structural schemes, to provide a thorough understanding of at least one implementation. It will be apparent to one skilled in art that implementations of present disclosure can be practiced without these specific details. In other instances, well-known features are described in lesser detail to not unnecessarily obscure at least one implementation. Furthermore, it can be understood that at least one implementation shown in a figure can be an illustrative representation and may not be necessarily drawn to scale.

In some instances, well-known methods and devices are shown in block diagram form, rather than in detail, to avoid obscuring at least one implementation. Reference throughout this specification to “an implementation” or “at least one implementation” or “one implementation” or “some implementations” means that a particular feature, structure, function, or characteristic described in connection with implementation can be included in at least one implementation. Thus, appearances “in an implementation” or “in one implementation” or “in at least one implementation” or “some implementations” in various places throughout this specification are not necessarily referring to a same implementation. Furthermore, particular features, structures, functions, or characteristics can be combined in any suitable manner in at least one implementation. For example, a first implementation can be combined with a second implementation anywhere particular features, structures, functions, or characteristics associated with first implementation and second implementation are not mutually exclusive.

Here, “coupled” and “connected,” along with their derivatives, can be used to describe functional or structural relationships between components. These terms are not intended as synonyms for each other. Rather, in particular implementations, “connected” can be used to indicate that two or more elements are in direct physical, optical, or electrical contact with each other. Here “coupled” can be used to indicate that two or more elements are in either direct or indirect (with other intervening elements between them) physical, electrical or in magnetic contact with each other, and/or that two or more elements co-operate or interact with each other (e.g., as in a cause an effect relationship).

Here, “over,” “under,” “between,” and “on” can generally refer to a relative position of one component or material with respect to other components or materials where such physical relationships are noteworthy. Unless these terms are modified with “direct” or “directly,” one or more intervening components or materials can be present. Similar distinctions are to be made in context of component assemblies. As used throughout this description, and in claims, a list of items joined by “at least one of” or “one or more of” can mean any combination of listed terms.

Here, “adjacent” can generally refer to a position of a thing being next to (e.g., immediately next to or close to with one or more things between them) or adjoining another thing (e.g., abutting it).

Unless otherwise specified in explicit context of their use, “substantially equal,” “about equal” and “approximately equal” can generally mean that there can be no more than incidental variation between two things so described. In at least one implementation, such variation can be no more than +/−10% of a referred value.

Here, “process tool” can generally refer to a piece of equipment employed in semiconductor fabrication, also referred to as a “semiconductor process tool” for semiconductor processing. In at least one implementation, process tool can generally comprise a vacuum chamber in which processes such as substrate plasma etching or plasma-enhanced material deposition are carried out. In at least one implementation, non-plasma related processes can also be performed in a process tool.

Here, “vacuum chamber” can generally refer to a chamber operable to hold a high vacuum (e.g., <10 torr). In at least one implementation, a vacuum chamber can be part of a process tool employed in semiconductor device fabrication. In at least one implementation, processes such as thin film deposition and etching can be performed in a vacuum chamber.

Here, “process chamber” can generally refer to a vacuum chamber of a process tool into which a substrate can be introduced for processing. In at least one implementation, process chamber can include a chuck for holding substrate. In at least one implementation, process chamber can be a plasma etch chamber.

Here, “substrate” can generally refer to a wafer comprising a semiconductor (e.g., silicon) or an insulator (e.g., aluminum nitride, silicon carbide, silicon nitride, aluminum oxide, float glass, borosilicate glass, etc.). In at least one implementation, a wafer can be a slice of monocrystalline semiconductor or insulator. In at least one implementation, a wafer can also comprise a polycrystalline or an amorphous (glassy) material. In at least one implementation, wafer can have a diameter generally ranging between 100 mm to 500 mm, and a thickness generally ranging between 100 microns and 1 mm.

Here, “pedestal” can generally refer to a processing component apparatus within a vacuum chamber. In at least one implementation, a pedestal can comprise a platen and a stem supporting platen. In at least one implementation, platen can hold a wafer substrate for processing within vacuum chamber. In at least one implementation, platen can have electrodes embedded within that are operable to function as plasma coupling electrodes and electrostatic clamping electrodes, for example.

Here, “platen” can generally refer to a flat widened portion of pedestal that can be operable for mounting a wafer substrate thereupon.

Here, “stem” can generally refer to a tubular member extending below platen. In at least one implementation, stem can house electrical conductors and tubing that can be routed to platen from components within pedestal assembly.

Here, “pedestal assembly” can generally refer to an assembly including a pedestal. In at least one implementation, pedestal assembly can include components and subassemblies that mount in sequence below stem. In at least one implementation, pedestal can be uppermost component of pedestal assembly.

Here, “adapter tube” can generally refer to a cylindrical housing attached to stem. In at least one implementation, adapter tube can transition a pedestal assembly from pedestal to other components below pedestal in a pedestal assembly.

Here, “O-ring” can generally refer to a gasket or seal that comprises an elastomer.

Here, “joint” can generally refer to a junction between two tubular structures.

Here, “inner wall” can generally refer to an inner surface of a tubular structure.

Here, “cooling collar’ can generally refer to a component of a pedestal assembly that can be situated below adapter tube. In at least one implementation, a cooling collar can provide tubing for circulating a cooling fluid to effectuate heat transfer from portions of pedestal assembly. In at least one implementation, a cooling collar comprises a first half portion and a second half portion.

Here, “flange” can generally refer to a ring structure that comprises a plurality of bolt holes. In at least one implementation, a flange can be employed for attachment of components of a pedestal assembly. In at least one implementation, in context of a cooling collar, a flange can be a flat cylindrical portion of cooling collar.

Here, “neck” can generally refer to an extended cylindrical portion of a cooling collar. In at least one implementation, a neck can extend from an inner wall of a flange of a cooling collar.

Here, “internal conduit” can generally refer to a conduit that can be embedded within a flange of a cooling collar. In at least one implementation, an internal conduit can carry a circulating cooling fluid.

Here, “groove” can generally refer to an elongated trench on a surface of flange of a cooling collar. In at least one implementation, a groove can seat an external conduit such as a length of tubing that can be seated within groove.

Here, “transition conduit” can generally refer to a component of a pedestal assembly that can be situated below a cooling collar. In at least one implementation, a transition conduit can provide housing for conductors and tubing extending within a pedestal assembly. In at least one implementation, transition conduit can comprise a slot within a wall for keying orientation of rigid conductors that extend through transition conduit.

Here, “orientation ring” can generally refer to a component of a pedestal assembly that can be situated within a transition conduit. In at least one implementation, an orientation ring can provide a bracket for uniquely orienting conductors, for example, RF conductors, routed within a pedestal assembly.

Here, “keying strip” can generally refer to a component of a pedestal assembly that can be attached to an orientation ring. In at least one implementation, a keying strip can provide a means to orient an orientation ring to face a particular direction on a transition conduit. In at least one implementation, keying strip can insert into a slot in wall of a transition conduit.

Here, “attachment flange” can generally refer to a component of a pedestal assembly that can be situated below a transition conduit. In at least one implementation, an attachment flange can connect a transition conduit to an electrical enclosure below transition conduit.

Here, “RF conductor guide” can generally refer to a component of a pedestal assembly that can be attached to an orientation ring. In at least one implementation, a RF conductor guide can stabilize RF conductors extending within a transition conduit.

Here, “electrical enclosure” can generally refer to a box or enclosure housing electronic circuitry that can include electronic filters and tuning circuits. In at least one implementation, an electrical enclosure can comprise a number of electrical connectors for coupling external power sources. In at least one implementation, an electrical enclosure can be attached as bottom-most component of a pedestal assembly.

Here, “frame” can generally refer to a support framework that comprises extensible members. In at least one implementation, extensible members can comprise actuators enabling frame members to articulate by extension and contraction in length. In at least one implementation, a frame can be attached to a bottom wall or floor of a vacuum chamber and to a lower component of a pedestal assembly, such as an electrical enclosure. In at least one implementation, a frame can suspend pedestal assembly below vacuum chamber. In at least one implementation, a frame can move and tilt pedestal assembly.

Here, “anchor” can generally refer to a structure on extensible members of a frame that serve as a foot or other type of attachment structure.

Here, “extensible member” can generally refer to members of a frame that can extend or contract. In at least one implementation, extensible members can comprise small linear motors, for example.

Here, “vacuum bellows” can generally refer to a vacuum containment housing that comprises flexible walls. In at least one implementation, flexible walls have a series of folds like an accordion that enable walls to have sufficient flexibility to extend, compress and move laterally in various directions. In at least one implementation, vacuum bellows can contain a high vacuum. In at least one implementation, vacuum bellows can be employed as a flexible housing surrounding components of a vacuum chamber system that are external to the vacuum chamber. In at least one implementation, movement of the external components can be enabled by vacuum bellows.

Here, “radio frequency” can generally refer to electromagnetic radiation that oscillates at frequencies in a spectrum that can be substantially inclusive of frequencies between 10 kilohertz (kHz) and 1 terahertz (THz, or 10¹⁵ Hz). In at least one implementation, upper limit of radio frequency spectrum can extend to several hundred gigahertz (GHz). Radio frequency as a term can be commonly abbreviated to “RF”.

Here, “RF signal source” can generally refer to an electronic device that can generate electrical signals at radio frequency. In at least one implementation, RF signal source can be capable of outputting significant RF current (e.g., 1 ampere rms or greater) at significant voltages. In at least one implementation, RF signal sources for ICP antennas generally are capable of outputting up to hundreds of amperes at up to several hundred volts, generating significant electrical power.

Here, “RF conductor” can generally refer to rigid conductors that conduct RF currents. In at least one implementation, RF conductors can be routed within a pedestal assembly from an electrical enclosure to electrodes within a platen.

Here, “heater conductor” can generally refer to rigid or flexible conductors that are operable to conduct DC or very low frequency AC currents to heaters within a platen.

Here, “RF connector” can generally refer to a connector operable to connect RF feed line, such as coaxial transmission cable, to a mating socket on a device such as an electrical enclosure. In at least one implementation, an RF connector can comprise a coaxial socket.

Here, “mountable bracket” can generally refer to a bracket of an RF connector that can be mountable on an electrical enclosure.

Here, “retention bracket” can generally refer to a small plate that can be attachable to a mountable bracket of a RF connector. In at least one implementation, a retention bracket can retain an RF cable within a mountable bracket.

Here, “lock plate” can generally refer to a pivotable plate that can be attached to mountable bracket of an RF connector. In at least one implementation, a lock plate can be swiveled upward to close over mountable bracket. In at least one implementation, lock plate can restrict access to a coaxial connector plug that can be retained within mountable bracket.

Here, “lock tab” can generally refer to a tab, strip or bar that attaches to a lock plate. In at least one implementation, locking strip can enable lock plate to be secured to an electrical enclosure by a fastener.

Here, “heater connector” can generally refer to a connector operable to connect cable conducting DC or very low frequency (e.g., 60 Hz) AC current intended to power heaters in a platen of a pedestal assembly.

Here, “printed circuit board” can generally refer to dielectric boards operable to receive mounted electrical and electronic components. In at least one implementation, a printed circuit board (PCB) can comprise etched traces replacing wiring for compact and rigid design.

Here, “tunable element” can generally refer to a circuit element that can be mechanically or electrically tuned. In at least one implementation, a tunable element may be a variable capacitor or a variable inductor.

Here, “variable capacitor” can generally refer to a tunable capacitor having a set of stator plates and a set of movable plates interleaved with the stator plates. In at least one implementation, movable plates may be rotated in and out of coincidence with the stator plates. In at least one implementation, movable plates may be linearly moved into and out of coincidence with the stator plates. In at least one implementation, a variable capacitor may be a solid-state varactor diode. In at least one implementation, a variable capacitor can be part of a tuned circuit comprising one or more inductors. In at least one implementation, a variable capacitor can be tuned by rotating rotor plates with respect to stator plates.

Here, “variable inductor’ can generally refer to a tunable inductor such as a roller inductor that mechanically varies a tap point on a fixed coil, or a slug-tuned inductor that comprises a moveable rod-shaped core in and out of a fixed coil.

Here, “motor” can generally refer to a motor that can be operable to drive tuning structures of a tuning element. In at least one implementation, a motor may be mechanically coupled to a variable capacitor to linearly drive or rotate moveable plates of the variable capacitor. In at least one implementation, a motor can be mechanically coupled to a shaft of a variable capacitor or a roller inductor. In at least one implementation, a motor can also be coupled to a screw drive or worm gear that linearly drives a core slug in a slug-tuned inductor.

Here, “partition” can generally refer to a wall within an enclosure, such as an electrical enclosure. In at least one implementation, a partition can provide electromagnetic shielding for circuits within electrical enclosure, and also provide mounting surfaces for mechanical attachment of PCBs similar structures.

Here, “RF connector block” can generally refer to a rigid dielectric block comprising two or more receptacles for plug-in attachment of RF conductors.

Here, “heater connector block” can generally refer to a rigid dielectric block comprising two or more receptacles for plug-in attachment of heater conductors.

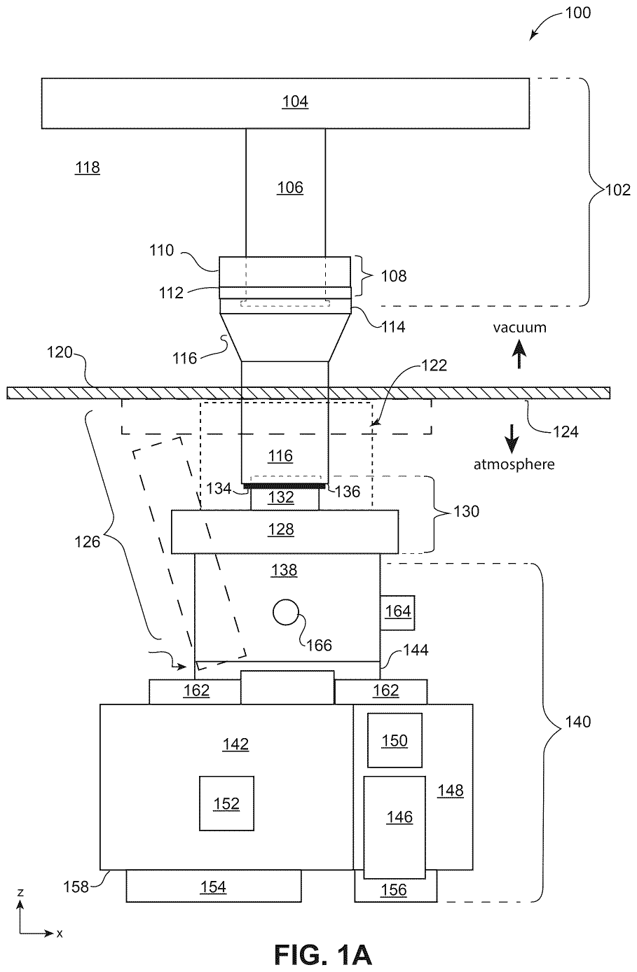

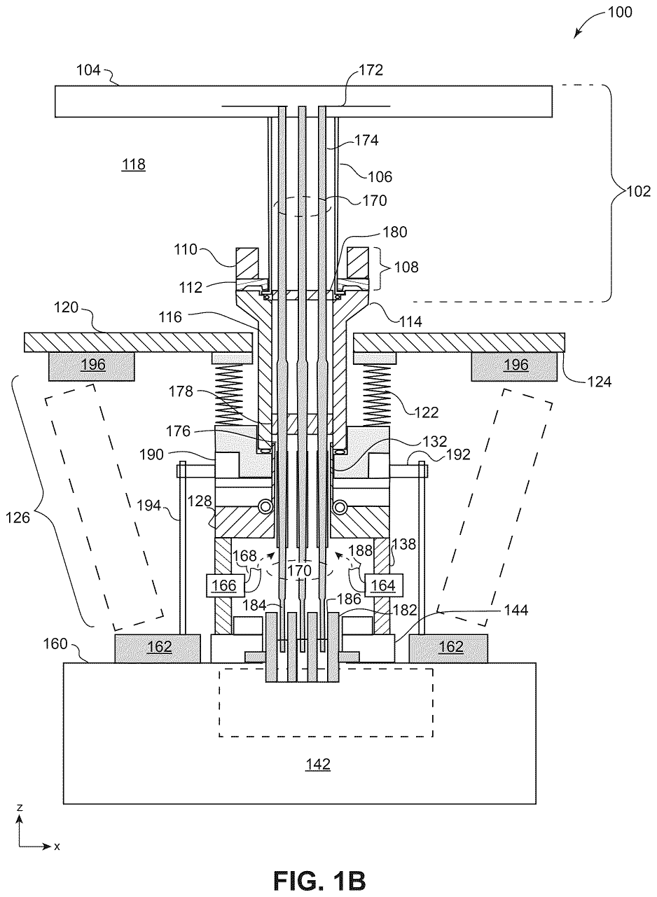

FIG. 1A illustrates a profile view of pedestal assembly 100, in accordance with at least one implementation. In at least one implementation, pedestal assembly 100 comprises pedestal 102. In at least one implementation, pedestal 102 comprises platen 104 and stem 106. In at least one implementation, stem 106 can be integrally formed with platen 104. In at least one implementation, pedestal 102 comprises a ceramic material, such as, but not limited to, aluminum nitride. Aluminum nitride (AlN) can be an electrical insulator (6.42 eV bandgap) but can have a high thermal conductivity of at least 300 W/mK. In at least one implementation, high thermal conductivity of aluminum nitride enables rapid and uniform heating of platen 104 to temperatures above 600° C. (melting point of AlN is 2200° C.). In at least one implementation, as stem 106 comprises AlN, heat can be readily transferred by conduction to components on a lower portion of pedestal assembly 100 below stem 106. In at least one implementation, some components in pedestal assembly 100 can have maximum temperature tolerances.

In at least one implementation, stem 106 comprises a base portion (indicated by hidden lines extending below stem 106) captured within clamp 108. In at least one implementation, clamp 108 comprises upper clamp ring 110 and lower clamp ring 112. In at least one implementation, upper clamp ring 110 and lower clamp ring 112 are bolted to flange 114 of adapter tube 116. In at least one implementation, stem 106 comprises a lip (shown in FIG. 1B) that compresses a compression seal seated inside of flange 114 when clamped.

In at least one implementation, pedestal assembly 100 can be partially within vacuum chamber 118 and partially outside of vacuum chamber 118. In at least one implementation, pedestal 102, clamp 108 and flange 114 are fully contained within vacuum chamber 118. In at least one implementation, adapter tube 116 extends through an opening (not shown) in floor 120 of vacuum chamber 118. In least one implementation, vacuum bellows 122 (shown by stippled box) contains lower portion of adapter tube 116. In at least one implementation, during operation, vacuum bellows 122 maintains a flexible vacuum compartment below vacuum chamber 118. In at least one implementation, vacuum bellows 122 comprises an upper flange (not shown) that can be fastened to external surface 124 of floor 120. In at least one implementation, floor 120 can be a bottom wall of vacuum chamber 118. In at least one implementation, a gasket can be included in subassembly to provide a vacuum seal. In at least one implementation, vacuum bellows 122 comprises a flexible wall extending below floor 120 that can enable movement of pedestal assembly 100 by actuators within frame 126. In at least one implementation, frame 126 is shown by dashed outlines so as not to obscure pedestal assembly 100. In at least one implementation, frame 126 is described below.

Referring again to pedestal assembly 100, in at least one implementation, adapter tube 116 terminates within vacuum bellows 122. In at least one implementation, vacuum bellows 122 comprises a lower flange (not shown) that can be fastened to a retainer ring. (e.g., retainer flange 190, see FIG. 1B) above flange 128 of cooling collar 130. In at least one implementation, a gasket can be included in assembly to provide a vacuum seal. In at least one implementation, cooling collar 130 comprises neck 132 that extends into adapter tube 116, forming a joint with adapter tube 116. In at least one implementation, o-ring 134 can be seated below rim 136 of adapter tube 116, forming a seal at joint between adapter tube 116 and neck 132. In at least one implementation, o-ring 134 comprises a suitable elastomer. In at least one implementation, an elastomer can have a maximum temperature rating. In at least one implementation, o-ring 134 may not be heated above 150° C.

In at least one implementation, cooling collar 130 accommodates a cooling fluid flowing within flange 128 or in tubing in contact with flange 128. In at least one implementation, cooling fluid can be water. In at least one implementation, during operation, flow rate of cooling fluid can be adjusted to maximize convective heat transfer from solid portions of cooling collar 130. In at least one implementation, cooling collar 130 comprises a material having a high thermal conductivity k (e.g., k greater than 200 W/mK). In at least one implementation, cooling collar 130 comprises aluminum (k~250 W/mK) or copper (k~400 W/mK). In at least one implementation, high thermal conductivity of solid portions of cooling collar 130 can enable sufficient cooling of neck 132 and adapter tube 116, protecting O-ring 134 from exposure to temperatures exceeding its thermal rating. Cooling collar 130 is further described below.

In at least one implementation, flange 128 of cooling collar can be fastened to transition conduit 138. In at least one implementation, transition conduit 138 can be part of electrical subassembly 140. In at least one implementation, transition conduit 138 provides a transitional housing for electrical conductors routed to extend through pedestal assembly 100. In at least one implementation, both RF and DC conductors (not shown) extend upwards through a pedestal column including cooling collar 130, adapter tube 116 and stem 106. In at least one implementation, electrical conductors originate within electrical enclosure 142, attached to attachment flange 144 between transition conduit 138 and electrical enclosure 142 of electrical subassembly 140. Transition conduit 138 and attachment flange 144 are further described below.

In at least one implementation, electrical enclosure 142 provides a nexus of connections between external power sources and conductors transferring RF and DC power to RF plasma coupling electrodes, electrostatic clamping electrodes and heaters within platen 104. In at least one implementation, electrical enclosure 142 houses circuitry for filtering RF that can be coupled to DC heater conductors, and for adjusting impedances between RF power source and RF plasma electrodes in platen 104. In at least one implementation, electrical subassembly 140 also comprises RF connector 146 attached to side panel 148 of electrical enclosure 142. In at least one implementation, RF connector 146 comprises features that prevent loosening and tampering. RF connector 146 is further described below. In at least one implementation, electrical subassembly 140 comprises tuning motor 150 attached to side panel 148. In at least one implementation, tuning motor 150 can be coupled to a variable capacitor or a variable inductor mounted within electrical enclosure 142. A tuning element, such as a variable capacitor or a variable inductor, is described below. In at least one implementation, electrical subassembly 140 can also include heater connector 152 mounted on electrical enclosure 142.

In at least one implementation, cooling fans 154 and 156 are provided for air-cooling circuitry within electrical enclosure 142. In at least one implementation, cooling fans 154 and 156 can comprise one or more cooling fans mounted on lower panel 158 of electrical enclosure 142. In at least one implementation, forced air flow from cooling fans 154 and 156 can enter interior of electrical enclosure 142 through vent holes within lower panel 158.

In at least one implementation, electrical subassembly 140 can further include lower anchors 162 on upper panel 160 of electrical enclosure 142. In at least one implementation, lower anchors 162 attach frame 126 to electrical enclosure 142. In at least one implementation, frame 126 enables suspension of pedestal assembly 100 from floor 120 of vacuum chamber 118. In at least one implementation, frame 126 can be operable to move pedestal assembly vertically (in z-direction) and laterally (x and y directions), as well as pivot or tilt pedestal assembly by a small angle. In at least one implementation, vacuum bellows 122 can accommodate positional changes of pedestal assembly 100 while maintaining vacuum within chamber 118. In at least one implementation, tilt angle of pedestal assembly 100 can be limited to less than one or two degrees. In at least one implementation, adjustment of x, y, z and theta positions of pedestal assembly 100 can be performed to optimize uniformity of films deposited on wafer substrates mounted on platen 104.

In at least one implementation, electrical subassembly 140 can further include thermocouple connector 164 mounted on transition conduit 138. In at least one implementation, thermocouple connector 164 terminates thermocouple leads routed within transition conduit 138. In at least one implementation, thermocouple leads are routed through a shield tube that can be mechanically coupled to thermocouple connector 164. In at least one implementation, thermocouple connector 164 can be electrically grounded to electrical enclosure 142 through transition conduit 138, also grounding shield tube to electrical enclosure 142. In at least one implementation, shielding of thermocouple leads can mitigate or eliminate RF noise interference on thermocouple signal from nearby RF conductors, enabling more accurate temperature readings.

FIG. 1B illustrates a cross-sectional view of pedestal assembly 100, showing internal components, according to at least one implementation. In at least one implementation, pedestal assembly 100 comprises RF conductors 170 extending from electrical enclosure 142 to platen 104. RF conductors 170 pass through transition conduit 138, adapter tube 116 and stem 106 to terminate at electrodes 172 embedded within platen 104. In at least one implementation, RF conductors are rigid structures. In at least one implementation, RF conductors 170 comprise solid rod portions 174 and hollow tubular portions 176. In at least one implementation, hollow tubular portions 176 can be thermal chokes that impede conductive heat transfer from platen 104. In at least one implementation, ceramic sleeves (not shown) can jacket portions of RF conductors 170 to limit radiative heat transfer and to limit arcing between conductors.

In at least one implementation, RF conductors 170 are constrained laterally within apertures of clamp 178, positioned at base of adapter tube. In at least one implementation, clamp 178 can be shaped to insert into adapter tube 116 in a specific orientation. In at least one implementation, adapter tube 116 can comprise internal contours (not shown) that complement shape of clamp 178, enabling orientation of clamp 178 within adapter tube 116. In at least one implementation, RF conductors 170 can be stabilized by spacer 180 positioned near top of adapter tube 116. In at least one implementation, spacer 180 can ensure minimal spacing between RF conductors 170 to avoid arcing between individual RF conductors 170.

In at least one implementation, RF conductors 170 are connected to circuitry housed within electrical enclosure 142 by connector block 182. In at least one implementation, bases 184 of RF conductors 170 seat within receptacles 186 embedded within connector block 182. In at least one implementation, bases 184 have a bayonet shape to insert and lock into connector block 182. In at least one implementation, bases 184 can insert into spring-loaded terminal receptacles to produce a secure electrical and mechanical connection. In at least one implementation, connector block 182 can comprise threaded caps at receptacles 186, which can be tightened about RF conductors 170 to secure them in place. In at least one implementation, connector block 182 can be mounted on a printed circuit board (PCB) (shown by hidden outline) within electrical enclosure 142. In at least one implementation, connector block 182 can extend through an opening (not shown) within upper panel 160 of electrical enclosure 142 and through attachment flange 144, into transition conduit 138.

In at least one implementation, heater conductors (not shown) comprise rigid rods that extend from electrical enclosure 142 to contact heaters (not shown) within platen 104. In at least one implementation, during operation, heater conductors can carry smaller currents than carried by RF conductors 170 (e.g., 20 amperes rms RF current) and have correspondingly smaller diameters than RF conductors 170. In at least one implementation, heater conductors can couple to circuitry within electrical enclosure 142 by a separate connector block adjacent to connector block 182, as described below.

In at least one implementation, inert gas inlet 166 passes through wall of transition conduit 138. In at least one implementation, duct 168 extends into adapter tube 116 and can be routed into stem 106 (indicated by dashed arrow). In at least one implementation, duct 168 can carry inert gas into stem 106 to avoid oxidative breakdown of stem 106 and platen 104. In at least one implementation, thermocouple connector 164 passes through wall of transition conduit 138. In at least one implementation, shield tube 188, also extending through transition conduit 138 into adapter tube 116 and stem 106, can be mechanically and electrically coupled to thermocouple connector 164. In at least one implementation, shield tube can be electrically grounded to electrical enclosure 142 through transition conduit 138 and attachment flange 144. In at least one implementation, thermocouple leads can be routed through shield tube 188 to prevent RF pickup from nearby RF conductors 170.

In at least one implementation, frame 126 can be attached to upper panel 160 of electrical enclosure 142 by lower anchors 162. In at least one implementation, lower anchors 162 can be fastened by screws or bolts to upper panel 160. In at least one implementation, pedestal assembly 100 can comprise retainer flange 190 above cooling collar 130. In at least one implementation, retainer flange190 comprises lateral extensions 192 that provide passage holes for long bolts 194 to prevent relative motion of components in lower portion of pedestal assembly 100, including cooling collar 130, transition conduit 138 and electrical enclosure 142. In at least one implementation, by means of retainer flange 190, these components be securely attached to vacuum bellows 122. In at least one implementation, frame 126 comprises upper anchors 196 for attachment to floor 120 of vacuum chamber 118.

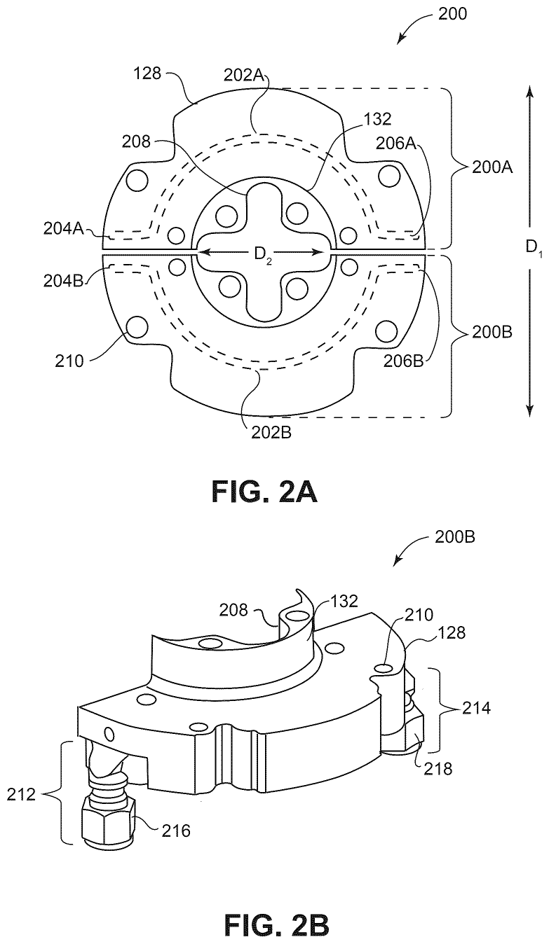

FIG. 2A illustrates a plan view of cooling collar 200, in accordance with at least one implementation. In at least one implementation, cooling collar 200 can be an exemplary implementation of cooling collar 130, shown in FIG. 1B. In at least one implementation, cooling collar 200 comprises two substantially identical half portions, half portion 200A and half portion 200B. In at least one implementation, cooling collar comprises flange 128 and neck 132. In at least one implementation, flange 128 and neck 132 are equally divided on half portions 200A and 200B. In at least one implementation, flange 128 has a diameter D₁ that can be approximately same as adjacent components, such as transition conduit 138, within pedestal assembly 100. In at least one implementation, during assembly of pedestal assembly 100, half portion 200A can be joined to half portion 200B by abutting both half portions together. In at least one implementation, half portions 200A and 200B comprise internal conduits 202A and 202B (shown by hidden lines), respectively. In at least one implementation, internal conduits 202A and 202B are independent from each other. In at least one implementation, internal conduits 202A and 202B are operable to carry a flowing cooling fluid such as water, providing convective heat transfer from solid portions of cooling collar 130. In at least one implementation, internal conduits 202A and 202B comprise ports 204A/B and 206A/B, respectively. In at least one implementation, ports 204A/B and 206A/B can be symmetrical and can serve as either inlets or outlets for coupling a circulating cooling water source, for example. In at least one implementation, ports 204A/B and 206A/B can be coupled to fittings that are mounted on flange 128, as shown in FIG. 2B. In at least one implementation, cooling collar 130 comprises a high thermal conductivity (k) material (e.g., k>200 W/mK), such as, but not limited in scope to, copper or aluminum and alloys thereof. In at least one implementation, cooling collar 130 comprises a high thermal conductivity (e.g., k>300 W/mK) ceramic material such as aluminum nitride.

In at least one implementation, neck 132 has a diameter D₂ that can be approximately same as interior diameter of adapter tube 116, enabling neck 132 to fit inside base of adapter tube 116 in assembly. In at least one implementation, neck 132 comprises a convoluted internal wall 208. In at least one implementation, internal wall 208 comprises symmetric (as shown) or asymmetric contours that enable keying insertion orientation of RF conductors and heater conductors (e.g., RF conductors 170), which extend through cooling collar 130 in pedestal assembly 100. In at least one implementation, holes 210 are provided in flange 128 to enable passage of bolts or other types of fasteners for securing cooling collar 130 to vacuum bellows 122 and transition conduit 138 (see FIG. 1B).

FIG. 2B illustrates a 3D perspective view of one of half portions of cooling collar 200, shown in FIG. 2A (e.g., half portion 200B), in accordance with at least one implementation. In at least one implementation, fittings 212 and 214 are attached to flange 128 at ports 204B and 206B. In at least one implementation fittings 212 and 214 are substantially identical. Fittings 212 and 214 can be fastened onto flange 128 by bolts or screws. In at least one implementation, fittings comprise compression nuts 216 and 218, as shown. In at least one implementation, fittings 212 and 214 comprise other suitable connector types, such as a quick disconnect connector. In at least one implementation, fittings 212 and 214 can couple a circulating fluid source to cooling collar 130.

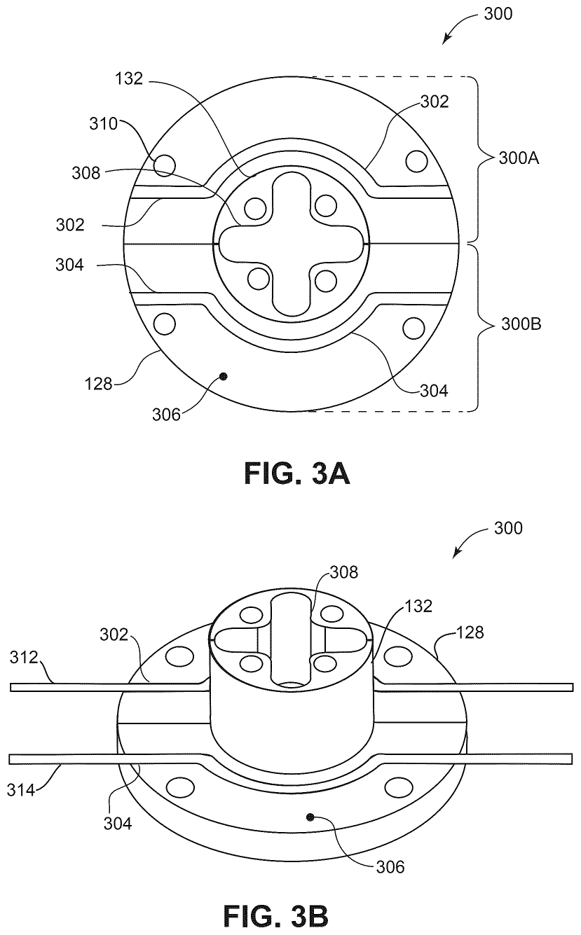

FIG. 3A illustrates a plan view of cooling collar 300, in accordance with at least one implementation. In at least one implementation, cooling collar 300 can be an exemplary implementation of cooling collar 130, shown in FIG. 1B. In at least one implementation, cooling collar 300 comprises two half portions, half portion 300A and half portion 300B. In at least one implementation, cooling collar 300 comprises flange 128 and neck 132 extending from an inner wall of flange 128. In at least one implementation, flange 128 and neck 132 are equally divided on both half portions 300A and 300B. In at least one implementation, flange 128 and neck 132 can have dimensions (e.g., D₁ and D₂) like those of cooling collar 200.

In at least one implementation, cooling collar 300 comprises grooves 302 and 304 on upper surface 306 of flange 128, respectively. In at least one implementation, grooves 302 and 304 can be substantially identical. In at least one implementation, grooves 302 and 304 provide a recessed path for routing external fluid-carrying tubing across flange 128, in contrast to internal conduit 202A/B employed in cooling collar 200. In at least one implementation, while grooves 302 and 304 are shown to follow gradual arcs, grooves 302 and 304 can have more convoluted geometries to extend surface contact, such as a serpentine geometry. In at least one implementation, grooves 302 and 304 can have a diameter and depth that can be adjusted for optimal heat transfer.

In at least one implementation, neck 132 comprises internal wall 308. In at least one implementation, internal wall 308 can have symmetric or asymmetric contours to enable keyed insertion of conductors, such as RF conductors 170, through neck 132. Holes 310 can be aligned to fastener holes in adjacent components, such as transition conduit 138 and vacuum bellows 122, to enable attachment of cooling collar 300 into pedestal assembly 100, as noted above.

FIG. 3B illustrates a 3D perspective view of cooling collar 300, in accordance with at least one implementation. In at least one implementation, tubing segments 312 and 314 extend within grooves 302 and 304, respectively. In at least one implementation, tubing segments 312 and 314 are shaped to follow contours of grooves 302 and 304. In at least one implementation, while tubing segments 312 and 314 follow simple arcs of grooves 302 and 304, tubing segments 312 and 314 can have more convoluted geometries to increase surface contact, such as serpentine geometries, to match convoluted geometries of grooves 302 and 304.

In at least one implementation, cooling collar 300 can include a gasket (not shown) over flange 128; providing an interface between cooling collar 300 (or generally cooling collar 130) and retainer flange 190, shown in FIG. 1B.

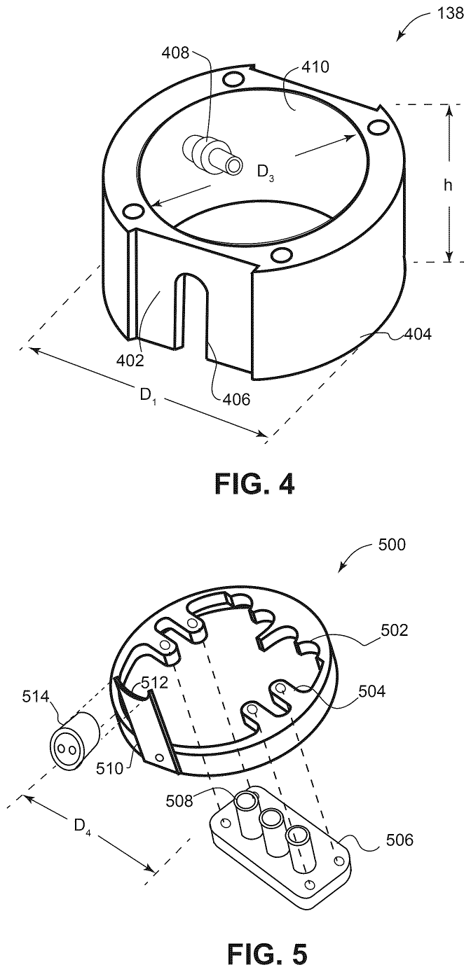

FIG. 4 illustrates a 3D perspective view of transition conduit 138, in accordance with at least one implementation. In at least one implementation, transition conduit 138 comprises a cylindrical body having a height h and overall diameter D₁ and an inner diameter D₃. In at least one implementation, transition conduit 138 can be an electrically conductive metallic structure that can be part of electrical subassembly 140 (see FIG. 1A). In at least one implementation, transition conduit 138 can serve as a transitional element between electrical enclosure 142 and upper portion of pedestal assembly 100, starting at cooling collar 130 (see FIG. 1B). In at least one implementation, transition conduit 138 can provide a protective enclosure for RF and DC conductors leading from electrical enclosure 142 to upper portion of pedestal assembly 100.

In at least one implementation, transition conduit 138 can comprise one or more flat portions 402 on exterior surface of outer sidewall 404. In at least one implementation, a slot 406 extends vertically (in z-direction) along outer sidewall 404. In at least one implementation, slot 406 can be positioned on flat portion 402. In at least one implementation, slot 406 provides a keying feature for orientation of connector blocks extending into transition conduit 138 from electrical enclosure 142, described below. In at least one implementation, as shown in FIG. 5, slot 406 can also provide a position for a thermocouple feedthrough connector.

In at least one implementation, transition conduit 138 comprises gas feedthrough connector 408. In at least one implementation, gas feedthrough connector 408 extends through outer sidewall 404 and inner wall 410, into interior of transition conduit 138. In at least one implementation, during operation, gas feedthrough connector 408 can provide coupling to an external source of an inert gas, such as nitrogen or argon. In at least one implementation, within transition conduit 138, gas feedthrough connector 408 can be connected to a tube (e.g., tube 188, FIG. 1B) that extends through cooling collar 130 and adapter tube 116 into stem 106. In at least one implementation, during operation, an inert gas such as nitrogen can be transported by tube (e.g., tube 188) into stem 106. In at least one implementation, inert gas can displace air from stem 106, thereby mitigating or avoiding potential oxidative damage to aluminum nitride composition of wall of stem 106.

FIG. 5 illustrates a 3D perspective view of orientation ring 500, in accordance with at least one implementation. In at least one implementation, orientation ring 500 has an outer diameter D₄ that can be approximately equal to inner diameter D₃ of transition conduit 138. In at least one implementation, orientation ring 500 inserts into transition conduit 138. In at least one implementation, orientation ring 500 comprises a keyed inner wall 502. In at least one implementation, inner wall 502 comprises contours that can conform to shape of connector blocks. In at least one implementation, inner wall 502 comprises extensions 504 for attaching RF conductor guide 506. In at least one implementation, RF conductor guide 506 comprises apertures 508 through which RF conductors 170 (see FIG. 1B) can extend. RF conductor guide 506 can stabilize RF conductors 170.

In at least one implementation, orientation ring 500 comprises keying strip 510. In at least one implementation, keying strip 510 inserts into slot 406 of transition conduit 138. In at least one implementation, when orientation ring 500 can be assembled with transition conduit 138, keying strip 510 and slot 406 can enable correct orientation of RF conductor guide 506, for example, so that RF conductors 170 can be oriented along a particular azimuth. In at least one implementation, keying strip 510 comprises notch 512 for mounting thermocouple connector 514. In at least one implementation, keying strip 510 comprises an electrically conductive material such as aluminum, copper or steel. In at least one implementation, thermocouple connector 514 can be electrically grounded to transition conduit 138 by keying strip 510 having mechanical contact with slot 406.

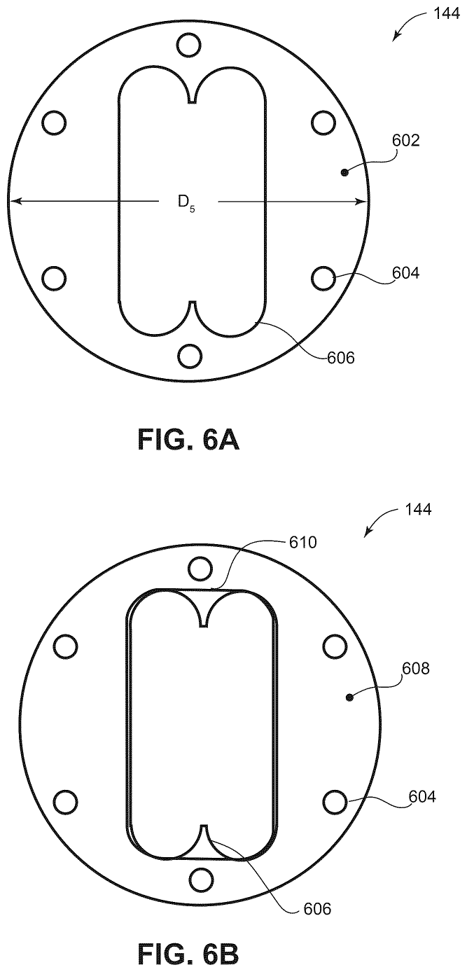

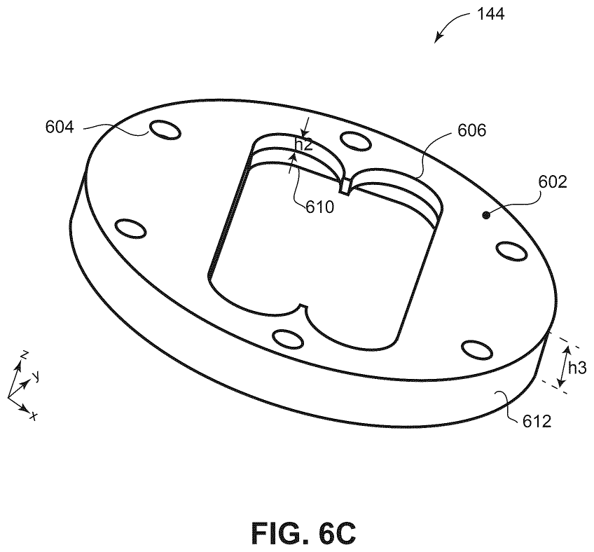

FIG. 6A illustrates a plan view of attachment flange 144, viewed from an upper surface 602, in accordance with at least one implementation. In at least one implementation, attachment flange 144 attaches lower rim of transition conduit 138 and upper portion of pedestal assembly 100, including cooling collar 130, adapter tube 116, stem 106 and platen 104, to electrical enclosure 142 (see FIG. 1B). In at least one implementation, attachment flange 144 has an outer diameter D₅ that can be approximately equal to diameter D₁ of transition conduit 138. In at least one implementation, attachment flange 144 comprises an electrically conductive material such as aluminum, copper or steel. In at least one implementation, attachment flange 144 comprises multiple bolt holes 604 for passage of bolts between electrical enclosure 142 and transition conduit 138. In at least one implementation, attachment flange 144 comprises cutout 606. In at least one implementation, cutout 606 can have approximately same size and shape of connector blocks (e.g., connector block 182, FIG. 1B) when connector blocks are adjacent to one another, as described below. In at least one implementation, connector blocks attached to upper panel 160 of electrical enclosure 142 extend into cutout 606 when assembled.

FIG. 6B illustrates a plan view of attachment flange 144, viewed from a lower surface 608, in accordance with at least one implementation. In at least one implementation, lower surface 608 can comprise aperture 610 immediately below cutout 606. In at least one implementation, aperture 610 can have a rectangular shape. In at least one implementation, aperture 610 can extend through a portion of thickness h₃ (e.g., height of sidewall 612) of attachment flange 144 (see FIG. 6C).

FIG. 6C illustrates a 3D perspective view of attachment flange 144 viewed from upper surface 602, in accordance with at least one implementation. In at least one implementation, cutout 606 extends in z-direction a distance h₂ that can be a portion of total thickness h₃ (e.g., height of sidewall 612) of attachment flange 144.

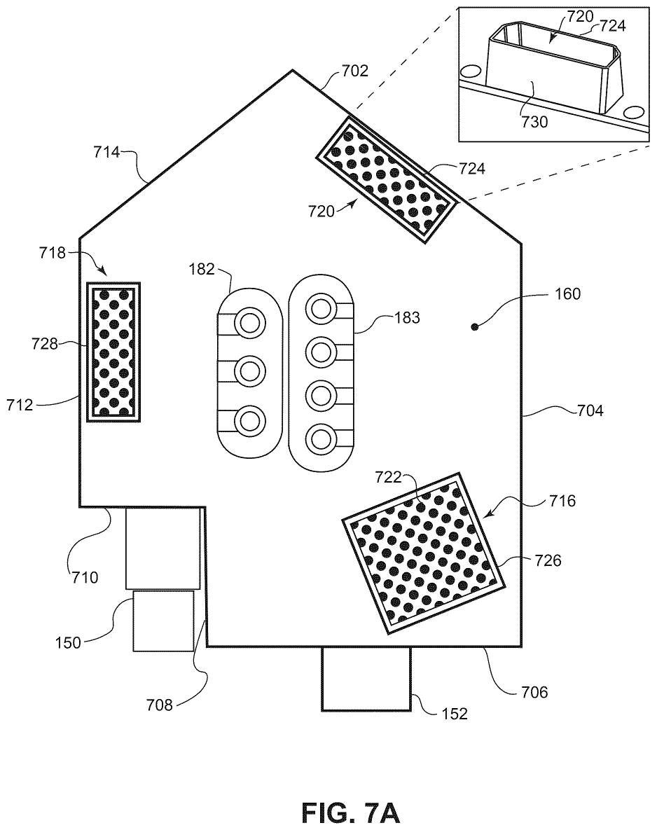

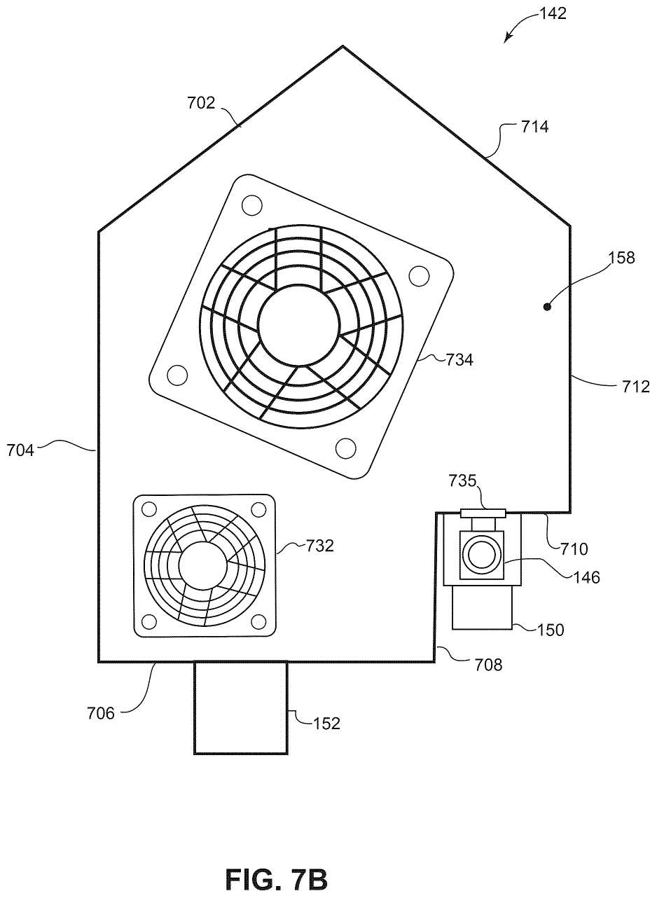

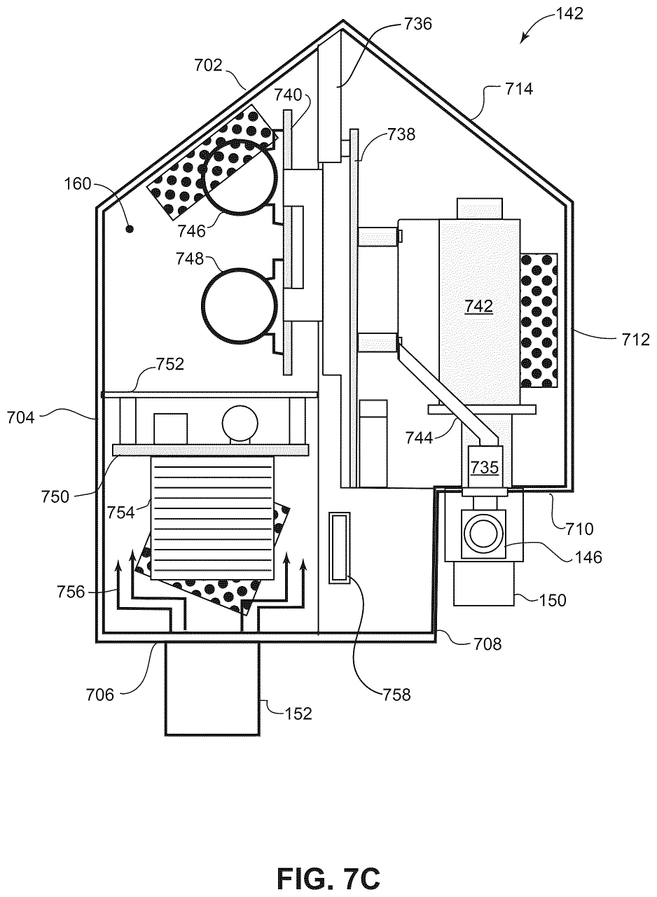

FIG. 7A illustrates a plan view of electrical enclosure 142, viewed from upper panel 160, in accordance with at least one implementation. In at least one implementation, electrical enclosure 142 comprises upper panel 160 and side panels 702, 704 706, 708, 710, 712, and 714. In at least one implementation, upper panel 160, lower panel and side panels (described below) comprise a sheet metal construction. In at least one implementation, connector blocks 182 and 183 extend through openings (not shown) in upper panel 160.

In at least one implementation, upper panel 160 comprises air vents 716, 718 and 720. In at least one implementation, while three air vents are shown, upper panel 160 can include any suitable number. In at least one implementation, air vents 716, 718, and 720 comprise pluralities of perforations 722 to allow air flow from cooling fans mounted on lower panel to blow over and cool parts of frame (e.g., frame 126) and pedestal assembly 100 that can be subject to heating. In at least one implementation, air vents 716-720 can comprise nozzles 724, 726, and 728 surrounding perforated areas of air vents. In at least one implementation, nozzles can be similar in shape to nozzle 724, shown in inset. Nozzles 724-728 have raised walls (e.g., wall 730) that can concentrate forced air exiting air vents 716-720 to structures above. In at least one implementation, nozzles 724-728 can also be employed as guide structures for aligning lower anchors 162 of frame 126, which attach to upper panel 160. In at least one implementation, heater connector 152 and tuning motor 150, described below, are attached to side panels 706 and 710, respectively.

FIG. 7B illustrates a plan view of electrical enclosure 142, viewed from lower panel 158, in accordance with at least one implementation. In at least one implementation, lower panel 158 comprises vent openings (not shown) and mounting holes (not shown) for cooling fans 732 and 734. In at least one implementation, while two cooling fans are shown, any suitable number of cooling fans can be employed. In at least one implementation, cooling fans 732 and 734 can provide forced air cooling for electrical components mounted inside of electrical enclosure 142 that are subject to heating. In at least one implementation, forced air can also exit through air vents 716-720 in upper panel 160 to help cool external components of pedestal assembly 100 and frame 126. In at least one implementation, RF connector 146 can be attached to side panel 710, above tuning motor 150. In at least one implementation, RF connector 146 may be connected to socket 735.

FIG. 7C illustrates a plan view of electrical enclosure 142, viewed from lower side with lower panel 158 removed to show interior of electrical enclosure 142 and circuitry, in accordance with at least one implementation. In at least one implementation, in plan view, upper panel 160 is shown below plane of figure. In at least one implementation, electrical enclosure 142 comprises partition 736. In at least one implementation, partition 736 comprises a sheet metal construction, similar or same as electrical enclosure 142. In at least one implementation, printed circuit board (PCB) 738 can be mounted on a first side of partition 736. In at least one implementation, PCB 740 can be mounted on a second side (opposite of first side) of partition 736. In at least one implementation, partition 736 can provide electromagnetic shielding to confine RF energy to one compartment (RF side) within electrical enclosure 142.

In at least one implementation, tunable element 742 can be mounted on PCB 738. In at least one implementation, tunable element 742 has electrical connections to PCB 738 through copper straps (not shown) or wires that couple tuning capacitor to traces on PCB 738. In at least one implementation, tunable element 742 can be a vacuum variable capacitor, enclosed within an air-tight housing. In at least one implementation, tuning motor 150 can be coupled to a shaft of tunable element 742. In at least one implementation, tuning motor 150 can actuate (e.g., rotate rotor plates or drive linearly translatable plates with respect to fixed stator plates) tunable element 742 for tuning purposes. In at least one implementation, tunable element 742 can be tuned to help match impedances between an RF feed line coupled to RF connector 146 and RF conductors 170. In at least one implementation, tuning motor 150 can be a stepper motor, for example, commanded by a controller. In at least one implementation, other suitable types of variable capacitors can be employed as tuning element 742.

In at least one implementation, tunable element 742 can be a tunable inductor. Examples of a tunable inductor can be a roller inductor or a slug-tuned inductor. In at least one implementation, other suitable variable inductors can be employed. In at least one implementation, tuning motor 150 is coupled to a shaft of a roller inductor tuning mechanism, or to a screw drive or worm gear mechanism that can linearly drive a rod-shape core slug in a slug-tuned inductor.

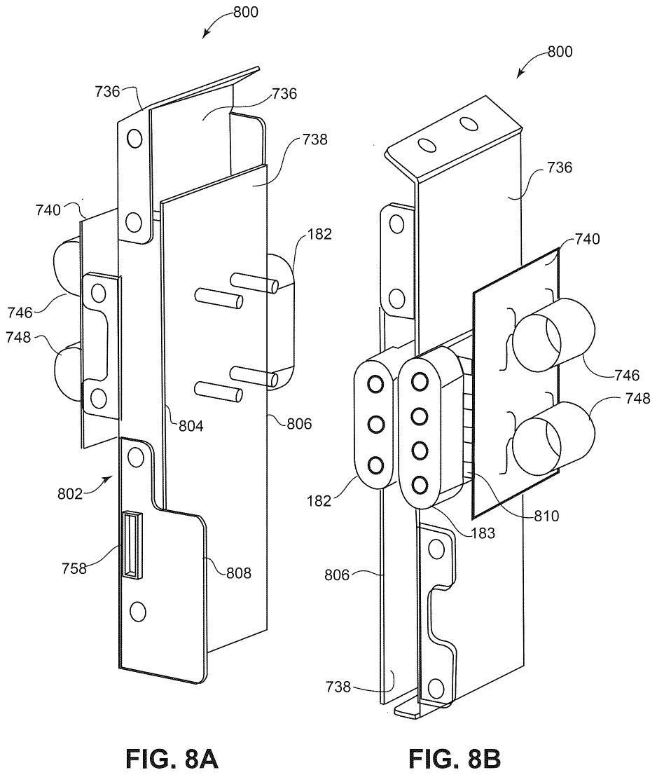

In at least one implementation, RF connector 146 can be coupled to tunable element 742 and to PCB 738 through a large cross-section conductor 744 such as a copper strap attached to socket 735, to accommodate large RF currents (e.g., greater than 20 amperes). In at least one implementation, traces on PCB 738 couple tunable element 742 to other components mounted on PCB 738. In at least one implementation, RF connector block 182 can be mounted on top side (e.g., below plane of figure) of PCB 738 (see FIG. 8B). In at least one implementation, RF connector block 182 can be coupled to RF connector 146 and a tuning circuit comprising tunable element 742 through traces on PCB 738.

In at least one implementation, PCB 740 comprises a filter circuit for suppression of RF voltages that can electromagnetically couple to heater supply circuit. In at least one implementation, filter circuit comprises inductors 746 and 748. Inductors 746 and 748 can be air wound coils. In at least one implementation, heater connector block 183 can be mounted on top side (e.g., below plane of figure) of PCB 740 (see FIG. 8B). In at least one implementation, heater connector block 183 can be coupled to filter circuitry on PCB 740.

In at least one implementation, low frequency (LF, sub-megahertz frequencies) filter circuit board (PCB 750) can be mounted on partition 752. In at least one implementation, partition 752 can be a sheet metal wall that extends orthogonally from partition 736. In at least one implementation, partition 752 can shield LF filter circuit on PCB 750 from RF that can be radiating from circuitry on PCB 740. In at least one implementation, LF filter circuit can comprise filter choke 754. In at least one implementation, conductors 756, which can be flexible wires or rigid conductors, can be routed from heater connector 152 to PCB 750. In at least one implementation, four conductors 756 can be employed to feed heater circuitry to carry heater current that can be nominally DC current (it can be understood that heater current can be low frequency (e.g., 60 Hz) AC as well).

In at least one implementation, LF circuitry on PCB 750 can be coupled to RF filter circuitry on PCB 740, sending DC current to PCB 740. In at least one implementation, ESC connector 758 can be provided for providing DC power for electrostatic clamping electrodes embedded within platen 104. In at least one implementation, ESC connector 758 can be coupled to PCB 740. In at least one implementation, DC power can be combined with RF power by circuitry on PCB 740, and delivered to electrodes within platen 104 by RF conductors 170.

FIG. 8A illustrates a 3D perspective view of filter board subassembly 800 viewed from rear side 802 of partition 736, in accordance with at least one implementation. In this perspective view, rear edge 804 of PCB 738 can be proximal to viewer. In at least one implementation, PCB 738 and PCB 740 are mounted on opposite sides of partition 736. In at least one implementation, tunable element 742 has been removed from PCB 738 to show RF connector block 182 mounted over front edge 806 of PCB 738. In at least one implementation, ESC connector 758 can be mounted on tab 808 of on rear side 802 of partition 736.

FIG. 8B illustrates a 3D perspective view of filter board subassembly 800 viewed from front side of partition 736, in accordance with at least one implementation. In this perspective view, front edge 806 of PCB 738 can be proximal to viewer. In at least one implementation, heater connector block 183 can be mounted on PCB 740 by solder leads 810. In at least one implementation, RF connector block 182 can be similarly mounted on PCB 738.

In at least one implementation, RF connector block 182 and heater connector block 183 are adjacent to one another. In at least one implementation, RF connector block 182 and heater connector block 183 extend through openings in upper panel 160 when assembled.

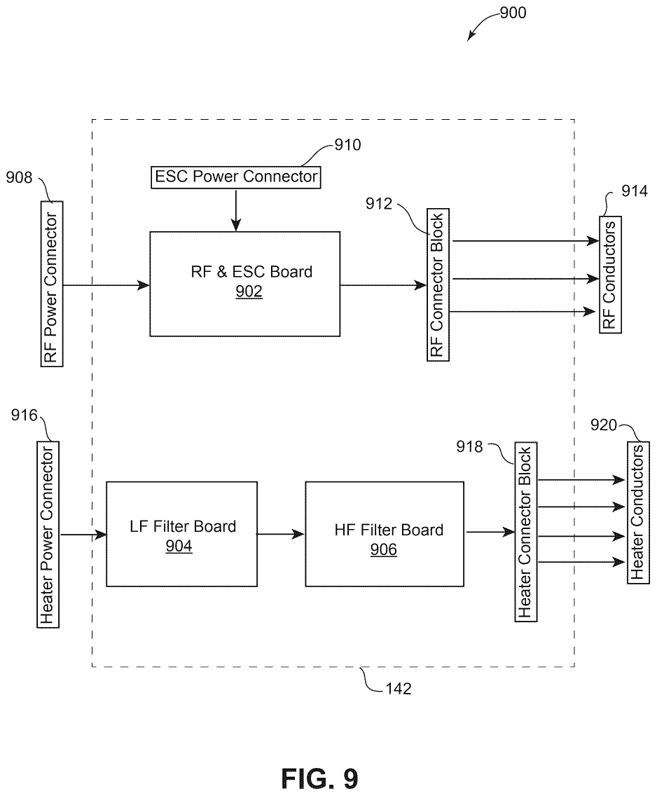

FIG. 9 illustrates a block diagram 900 of electronic circuitry contained within electrical enclosure 142, in accordance with at least one implementation. Arrow connectors between blocks indicate directionality of signals. In at least one implementation, circuitry within electrical enclosure 142 can be distributed on “RF & ESC” board 902, “LF Filter” board 904 and “HF Filter” board 906. In at least one implementation, “RF & ESC “board 902 can correspond to PCB 738 shown in FIGS. 7C and 8A. In at least one implementation, “LF Filter” board 904 can correspond to PCB 750 shown in FIG. 7C. In at least one implementation, “HF Filter” board 906 can correspond to PCB 740 shown in FIGS. 7C and 8B.

In at least one implementation, board 902 can be coupled to “RF power” input connector 908 and “ESC power” input connector 910. In at least one implementation, “RF power” input connector 908 can correspond to RF connector 146, shown in FIG. 7C. In at least one implementation, “ESC power” input connector 910 can correspond to ESC connector 758 also shown in FIG. 7C. In at least one implementation, raw RF power can be conditioned by tuning phase angle between RF voltage and current (e.g., by tuning of tunable element 742), for example, on board 902. In at least one implementation, DC power for electrostatic clamping of semiconductor wafers on platen 104 can be combined with RF power on board 902 (e.g., by a bias tee circuit). In at least one implementation, conditioned RF power can be output to “RF Connector” block 912 and out to RF conductors 914 (e.g., RF conductors 170).

In at least one implementation, “LF filter” board 904 can be coupled to “Heater power” input connector 916. In at least one implementation, “Heater power” input connector 916 can correspond to heater connector 152. LF frequencies (e.g., frequencies less than 1 MHz) appearing on heater power conductors can be suppressed by low pass filter circuitry on board 904 designed for very low frequencies (e.g., 60 Hz) or DC output. In at least one implementation, heater conductors are passed to “HF Filter” board 906 directly from board 904. In at least one implementation, board 906 can suppress any RF that can be coupled onto heater conductors by providing chokes or low pass filters. Conditioned heater power can be output to “heater connector” block 918, and to heater conductors 920.

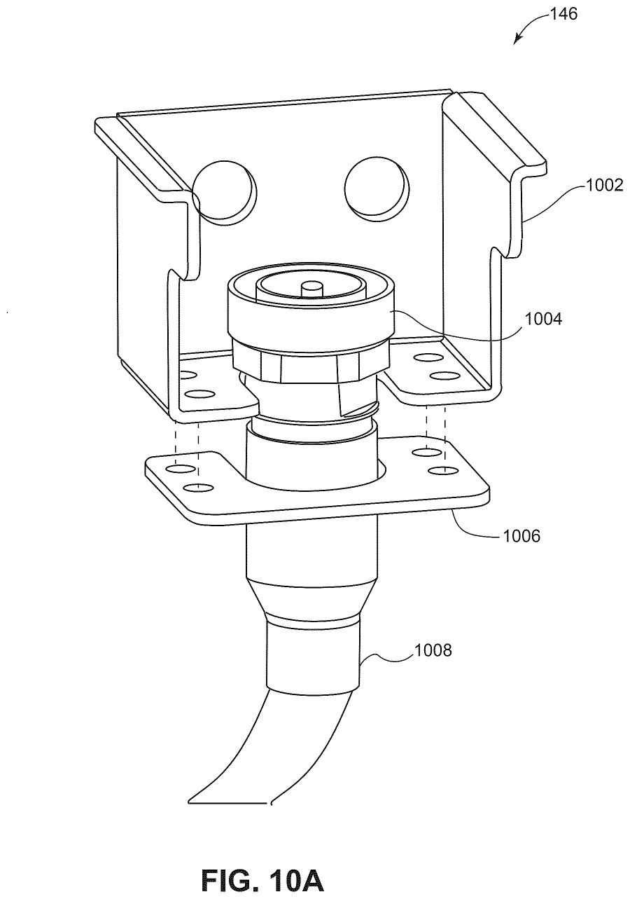

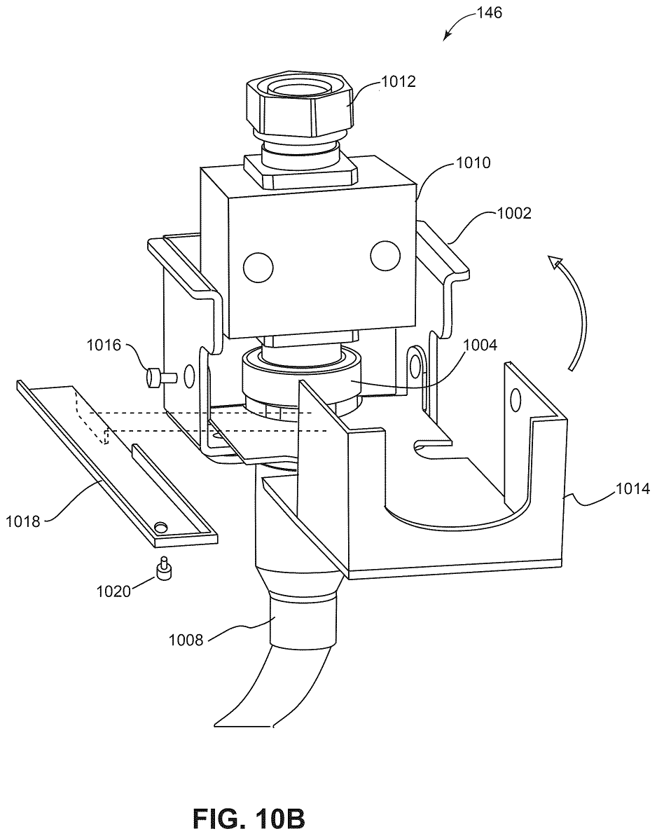

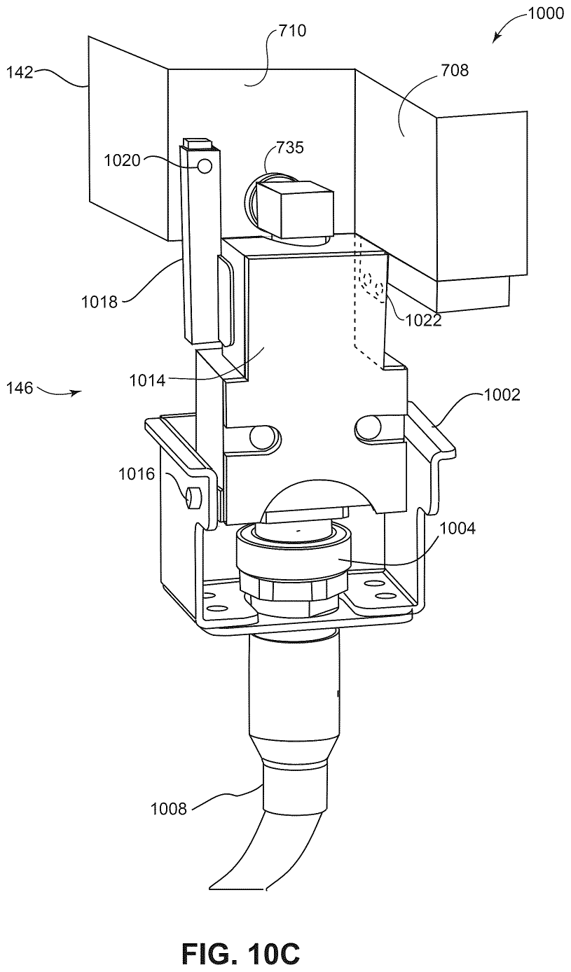

FIG. 10A illustrates a 3D perspective view of partially assembled RF connector 146, in accordance with at least one implementation. In at least one implementation, RF connector comprises mountable bracket 1002, and coaxial connector 1004 seated within mountable bracket 1002. In at least one implementation, coaxial connector 1004 terminates coaxial cable 1006. In at least one implementation, RF connector 146 comprises retainer plate 1008 to retain coaxial connector 1004 within mountable bracket 1002.

FIG. 10B illustrates a 3D perspective view of fully assembled RF connector 146, in accordance with at least one implementation. In at least one implementation, power module 1010 can be attached to coaxial connector 1004 and seated within mountable bracket 1002. In at least one implementation, power module 1010 can be fastened to mountable bracket 1002. In at least one implementation, power module 1010 comprises an output connector plug 1012 that can interface with a receptacle socket on electrical enclosure 142.

In at least one implementation, RF connector 146 comprises lock plate 1014. In at least one implementation, lock plate 1014 can be pivotally attached to mountable bracket 1002 by fasteners 1016. In at least one implementation, lock tab 1018 can be attached to lock plate 1014. In at least one implementation, lock tab 1018 can be operable to attach to electrical enclosure 142 by fastener 1020. In at least one implementation, lock tab 1018 can be a strip or bar structure that locks lock plate 1014 in place.

FIG. 10C illustrates a 3D perspective view of an implementation 1000 of RF connector 146, in accordance with at least one implementation. RF connector 146 is shown in an intended implementation. In at least one implementation, lock plate 1014 can be pivoted into locking position. In at least one implementation, lock tab can be fastened to cover coaxial connector 1004 and power module 1010 when assembled, preventing contact with or inadvertent loosening of coaxial connector 1004. In at least one implementation, lock tab 1018 can be fastened to side panel 710 of electrical enclosure 142 by fastener 1020, immobilizing mountable bracket 1002 and preventing twisting of coaxial connector 1004. In at least one implementation, mountable bracket 1002 can be further retained by fastening lock plate 1014 to tab 1022, extending from side panel 708.

Following examples are provided that illustrate various implementations. Here, examples can be combined with other examples. As such, various implementations can be combined with other implementations without changing scope of disclosure.
Example 1 is a pedestal assembly, comprising a pedestal comprising a platen and a stem attached to the platen, an adapter tube attached to the stem, a cooling collar coupled to the adapter tube, a transition conduit coupled to the cooling collar, and an electrical enclosure coupled to the transition conduit, wherein the electrical enclosure comprises a radio frequency (RF) connector block and a heater connector block, wherein RF conductors extend from the RF connector block to the platen, and wherein heater conductors extend from the heater connector block to the platen.
Example 2 is a pedestal assembly according to any example herein, in particular example 1, wherein the electrical enclosure comprises a first printed circuit board (PCB) comprising at least one RF circuit and at least one DC circuit.
Example 3 is a pedestal assembly according to any example herein, in particular example 2, wherein the at least one RF circuit comprises a tunable element, and wherein a motor is mechanically coupled to the tunable element.
Example 4 is a pedestal assembly according to any example herein, in particular example 3, wherein the tunable element is a variable capacitor.
Example 5 is a pedestal assembly according to any example herein, in particular example 3, wherein the tunable element is a variable inductor.
Example 6 is a pedestal assembly according to any example herein, in particular example 2, wherein the RF connector block is coupled to the first PCB.
Example 7 is a pedestal assembly according to any example herein, in particular example 1, wherein the electrical enclosure comprises a second PCB, wherein the second PCB comprises a filter circuit.
Example 8 is a pedestal assembly according to any example herein, in particular example 7, wherein the heater connector block is coupled to the second PCB.
Example 9 includes all features of example 1, wherein the RF connector block extends through an upper panel of the electrical enclosure.
Example 10 is a pedestal assembly according to any example herein, in particular example 9, wherein the heater connector block extends through the upper panel of the electrical enclosure.
Example 11 is a pedestal assembly according to any example herein, in particular example 1, wherein the electrical enclosure comprises an RF connector.
Example 12 is a pedestal assembly according to any example herein, in particular example 11, wherein the RF connector is attached to an RF socket on a side panel of the electrical enclosure.
Example 13 is a pedestal assembly according to any example herein, in particular example 11, wherein the RF connector comprises a mountable bracket, a retention bracket attached to the mountable bracket, wherein the retention bracket is operable to retain a cable connector within the mountable bracket, a lock plate pivotally attached to the mountable bracket, and a lock tab attached to the lock plate.
Example 14 is a pedestal assembly according to any example herein, in particular example 1, wherein the transition conduit comprises an orientation ring, wherein the orientation ring comprises a keying strip.
Example 15 is a pedestal assembly according to any example herein, in particular example 14, wherein the transition conduit comprises a slot in a sidewall, and wherein the keying strip is positioned within the slot.
Example 16 is a pedestal assembly according to any example herein, in particular example 14, wherein an RF conductor guide is attached to the orientation ring.
Example 17 is a pedestal assembly according to any example herein, in particular example 1, wherein an attachment flange is coupled to the transition conduit and couples the transition conduit to the electrical enclosure.
Example 18 is a pedestal assembly according to any example herein, in particular example 1, wherein the cooling collar comprises a flange and a neck, and wherein the neck extends from an inner wall of the flange.
Example 19 is a pedestal assembly according to any example herein, in particular example 18, wherein the neck is inserted into the adapter tube, and wherein an o-ring is seated at a joint between the adapter tube and the neck.
Example 20 is a pedestal assembly according to any example herein, in particular example 1, wherein the cooling collar comprises a first portion and a second portion, and wherein the first portion comprises a first internal conduit and the second portion comprises a second internal conduit.
Example 21 is a pedestal assembly according to any example herein, in particular example 1, wherein the cooling collar comprises a first portion and a second portion, wherein the first portion comprises a first groove on a first surface, and wherein the second portion comprises a second groove on a second surface.
Example 22 is a pedestal assembly according to any example herein, in particular example 21, wherein a first tubing is seated within the first groove, and a second tubing is seated within the second groove.
Example 23 is a semiconductor tool, comprising a vacuum chamber, a pedestal assembly, wherein the pedestal assembly comprises a pedestal comprising a platen and a stem attached to the platen, an adapter tube attached to the stem, a cooling collar coupled to the adapter tube, a transition conduit coupled to the cooling collar, and an electrical enclosure coupled to the transition conduit, wherein the electrical enclosure comprises a radio frequency (RF) connector block and a heater connector block, wherein RF conductors extend from the RF connector block to the platen, and wherein heater conductors extend from the heater connector block to the platen, wherein the semiconductor process tool further comprises an frame attached to the vacuum chamber, wherein the frame is coupled to the pedestal assembly.
Example 24 is a semiconductor tool according to any example herein, in particular example 23, wherein the frame comprises an upper anchor and a lower anchor, wherein the upper anchor is attached to a bottom wall of the vacuum chamber, and the lower anchor is attached to the electrical enclosure of the pedestal assembly.
Example 25 is a semiconductor tool according to any example herein, in particular example 24, wherein the pedestal assembly extends through the bottom wall of the vacuum chamber.
Example 26 is a semiconductor tool according to any example herein, in particular example 25, wherein a vacuum bellows is attached to the bottom wall for the vacuum chamber. and wherein the vacuum bellows is coupled to a retainer ring above the cooling collar of the pedestal assembly.

Besides what is described herein, various modifications can be made to disclosed implementations and implementations thereof without departing from their scope. Therefore, illustrations of implementations herein should be construed as examples, and not restrictive to scope of present disclosure.

What is claimed is:

1. A pedestal assembly, comprising:
a pedestal comprising a platen and a stem attached to the platen;
an adapter tube attached to the stem;
a cooling collar coupled to the adapter tube;
a transition conduit coupled to the cooling collar; and
an electrical enclosure coupled to the transition conduit, wherein the electrical enclosure comprises a radio frequency (RF) connector block and a heater connector block, wherein the RF connector block is coupled to the platen, and wherein the heater connector block is coupled to the platen.

2. The pedestal assembly of claim 1, wherein the electrical enclosure comprises a first printed circuit board (PCB) comprising at least one RF circuit and at least one DC circuit.

3. The pedestal assembly of claim 2, wherein the at least one RF circuit comprises a tunable element, and wherein a motor is mechanically coupled to the tunable element.

4. The pedestal assembly of claim 3, wherein the tunable element is a variable capacitor.

5. The pedestal assembly of claim 3, wherein the tunable element is a variable inductor.

6. The pedestal assembly of claim 2, wherein the RF connector block is coupled to the first PCB.

7. The pedestal assembly of claim 1, wherein the electrical enclosure comprises a second PCB, wherein the second PCB comprises a filter circuit.

8. The pedestal assembly of claim 7, wherein the heater connector block is coupled to the second PCB.

9. The pedestal assembly of claim 1, wherein the RF connector block extends through an upper panel of the electrical enclosure.

10. The pedestal assembly of claim 9, wherein the heater connector block extends through the upper panel of the electrical enclosure.

11. The pedestal assembly of claim 1, wherein the electrical enclosure comprises an RF connector.

12. The pedestal assembly of claim 11, wherein the RF connector is attached to an RF socket on a side panel of the electrical enclosure.

13. The pedestal assembly of claim 11, wherein the RF connector comprises:
a mountable bracket;
a retention bracket attached to the mountable bracket, wherein the retention bracket is operable to retain a cable connector within the mountable bracket;
a lock plate pivotally attached to the mountable bracket; and
a lock tab attached to the lock plate.

14. The pedestal assembly of claim 1, wherein the transition conduit comprises an orientation ring, wherein the orientation ring comprises a key strip.

15. The pedestal assembly of claim 14, wherein the transition conduit comprises a slot in a sidewall, and wherein the key strip is positioned within the slot.

16. The pedestal assembly of claim 14, wherein an RF conductor guide is attached to the orientation ring.

17. The pedestal assembly of claim 1, wherein an attachment flange is coupled to the transition conduit and couples the transition conduit to the electrical enclosure.

18. The pedestal assembly of claim 1, wherein the cooling collar comprises a flange and a neck, and wherein the neck extends from an inner wall of the flange.

19. The pedestal assembly of claim 18, wherein the neck is inserted into the adapter tube, and wherein an o-ring is seated at a joint between the adapter tube and the neck.

20. The pedestal assembly of claim 1, wherein the cooling collar comprises a first portion and a second portion, and wherein the first portion comprises a first internal conduit and the second portion comprises a second internal conduit.

21. The pedestal assembly of claim 1, wherein the cooling collar comprises a first portion and a second portion, wherein the first portion comprises a first groove on a first surface, and wherein the second portion comprises a second groove on a second surface.

22. The pedestal assembly of claim 21, wherein a first tubing is seated within the first groove, and a second tubing is seated within the second groove.

23. A semiconductor process tool, comprising:
a vacuum chamber; and
a pedestal assembly, wherein the pedestal assembly comprises:
a pedestal comprising a platen and a stem attached to the platen;
an adapter tube attached to the stem;
a cooling collar coupled to the adapter tube;
a transition conduit coupled to the cooling collar; and
an electrical enclosure coupled to the transition conduit, wherein the electrical enclosure comprises a radio frequency (RF) connector block and a heater connector block, wherein the RF connector block is coupled to the platen, and wherein the heater connector block is coupled to the platen, wherein the semiconductor process tool further comprises:
a frame attached to the vacuum chamber, wherein the frame is coupled to the pedestal assembly.

24. The semiconductor process tool of claim 23, wherein the frame comprises an upper anchor and a lower anchor, wherein the upper anchor is attached to a bottom wall of the vacuum chamber, and the lower anchor is attached to the electrical enclosure of the pedestal assembly.

25. The semiconductor process tool of claim 24, wherein the pedestal assembly extends through the bottom wall of the vacuum chamber, wherein a vacuum bellows is attached to the bottom wall of the vacuum chamber and wherein the vacuum bellows is coupled to a retainer ring above the cooling collar of the pedestal assembly.
